(19) United States
(12) Patent Application Publication
(10) Pub. No.: US 2015/0348755 A1
(43) Pub. Date: Dec. 3, 2015

(54) GAS DISTRIBUTION APPARATUS AND SUBSTRATE PROCESSING APPARATUS INCLUDING SAME

(71) Applicant: CHARM ENGINEERING CO., LTD., Yongin-Si (KR)

(72) Inventors: Young-Ki HAN, Seoul (KR); Young-Soo SEO, Osan-Si (KR); Suk Ki MIN, Pyeongtaek-Si (KR); Jun-Hyeok LEE, Osan-Si (KR); Kyu-Sang LEE, Goyang-Si (KR)

(21) Appl. No.: 14/708,232

(22) Filed: May 9, 2015

(30) Foreign Application Priority Data
May 29, 2014 (KR) 10-2014-0064956
Oct. 14, 2014 (KR) 10-2014-0138223

(51) Int. Cl. H01J 37/32

(52) U.S. Cl. CPC H01J 37/3244; H01J 37/32357; H01J 37/32669

(57) ABSTRACT

Provided is a gas distribution apparatus including first and second regions vertically separated therein. In the first region, a first process gas supplied to the first region from the outside is injected after being excited into a plasma state, and in the second region, a second process gas supplied after being excited into a plasma state from the outside is injected after being accommodated.

### BACKGROUND

The present disclosure relates to a gas distribution apparatus, and more particularly to, a gas distribution apparatus capable of improving process uniformity on a substrate by using dual plasma and a substrate processing apparatus including the same.

In general, semiconductor devices, display devices, light-emitting diodes or thin film solar batteries are manufactured by using a semiconductor process. A semiconductor process includes a thin film deposition process for depositing a thin film of a specific material on a substrate, a photolithography process for exposing or covering a selected region of the thin film using a photoresist, and an etching process for removing and patterning the thin film in a selected region. The semiconductor process is repeatedly performed a plurality of times to form a desired multi-layered structure. Such a semiconductor process is conducted within a reaction chamber which has an optimal environment for a corresponding process.

The reaction chamber includes a substrate supporting member for supporting a substrate and a gas distribution part for injecting a process gas, which are provided facing each other inside the reaction chamber, and a gas supply part for supplying the process gas outside the reaction chamber. That is, at an inner lower side of the reaction chamber, the substrate supporting member is provided to support a substrate, and at an inner upper side of the reaction chamber, the gas distribution part is provided to inject the process gas supplied from a gas supply part onto the substrate. Here, for example, the thin film deposition process may simultaneously supply at least one process gas forming a thin film (CVD method), or sequentially supply at least two process gases into the reaction chamber (ALD method). Also, as substrates become larger, it is required that thin films are deposited or etched over entire areas of the substrates to maintain process uniformity. For this, a gas distribution apparatus of a shower head type capable of uniformly injecting a process gas onto a wide region has been widely used. An example of such a shower head is disclosed in Korean Patent Application Laid-open Publication No. 2008-0020202.

Also, a plasma apparatus for activating and plasmarizing a process gas may be used to manufacture a high-integrated and miniaturized semiconductor device. Plasma apparatuses are typically classified in accordance with plasmarizing methods into capacitive coupled plasma (CCP) apparatuses and inductive coupled plasma (ICP) apparatuses. The CCP apparatus has an electrode in a reaction chamber, and the ICP apparatus has an antenna, which is provided outside a reaction chamber to which a power source is applied, so that the plasma of a process gas may be generated inside the reaction chamber. Such a CCP type plasma apparatus is disclosed in Korean Patent Laid-open Publication No. 1997-0003557, and an ICP type plasma apparatus is disclosed in Korean Paten Laid-open No. 10-0963519.

Meanwhile, since the plasma of a process gas is generated inside a reaction chamber, troubles etc. due to heat and plasma may occur, for example, thin film with a thickness less than 20 nm may be damaged by the plasma. To solve such limitations, remote plasma is developed, which generates the plasma of a process gas outside a reaction chamber and supplying the plasma into the reaction chamber. Also, research in which dual plasma sources are used so as to minimize damage due to plasma has been carried out. However, the plasma of process gases generated from the dual plasma generating sources may not be uniformly bound on a substrate and thus has a limitation in process uniformity.

### SUMMARY

The present disclosure provides a substrate processing apparatus capable of preventing damage to a substrate due to plasma.

The present disclosure also provides a gas distribution apparatus capable of uniformly distributing the process gas activated through dual plasma onto a substrate, and accordingly, capable of improving process uniformity on the substrate, and a substrate processing apparatus including the gas distribution apparatus.

In accordance with an exemplary embodiment, a gas distribution apparatus includes first and second regions vertically separated therein; in the first region, a first process gas supplied to the first region from the outside may be injected after being excited into a plasma state in the first region; and in the second region, a second process gas supplied after being excited into a plasma state from the outside is injected after being accommodated.

The above gas distribution apparatus may further include an upper plate, a middle plate, and a lower plate, which are vertically spaced apart from one another, wherein a space between the upper plate and the middle plate is the second region, and a space between the middle plate and the lower plate is the first region.

The middle plate may be applied with a radio frequency power, the lower plate may be grounded, and an insulation member may be provided between the middle plate and the lower plate.

The above gas distribution apparatus may include an upper plate, a middle plate, and a lower plate, which are vertically spaced apart from another, wherein a space between the upper plate and the middle plate is the second region, and a space between the middle plate and the lower plate is the first region.

The upper plate may be applied with a radio frequency power, the middle plate may be grounded, and an insulation member may be provided between the upper plate and the middle plate.

The above gas distribution apparatus may further include a plurality of injection nozzles penetrating the lower plate from the middle plate.

The middle plate may be formed with a plurality of first through holes, through which the plurality of nozzles pass, and the lower plate may be formed with a plurality of second through holes, through which the plurality of nozzles pass, and a plurality of third through holes for injecting a process gas in a region between the middle plate and the lower plate.

The second and third through holes may be formed with the same size and number.

A stepped portion having a diameter larger than that of the first through hole may be provided at an upper portion of the first through hole of the middle plate, and an upper portion of the injection nozzle may be supported by the stepped portion.

The above gas distribution apparatus may further include a cover plate having one surface contacting an upper surface of the middle plate and a plurality of through holes formed therein.

The above gas distribution apparatus may further include a diffusing plate provided between the upper plate and the middle plate and having a plurality of through holes formed therein.

The above gas distribution apparatus may further include a gap adjusting member provided at least one portion of upper and lower sides of the insulation member and having a same shape as the insulation member.

In another exemplary embodiment, a substrate processing apparatus includes: a reaction chamber having a predetermined reaction space; a substrate support part provided within the reaction chamber to support a substrate; a gas distribution part 400 provided to face the substrate supporting member and including first and second regions vertically separated therein, wherein in the first region, a first process gas supplied to the first region from the outside is injected after being excited into a plasma state, and in the second region, a second process gas supplied after being excited into a plasma state from the outside is injected after being accommodated; and a plasma generation part for generating plasma of a process gas outside the reaction chamber and inside the gas distribution part.

The above substrate processing apparatus may further include a process gas supply part including a first process gas supply tube supplying the first process gas to the first region, and a second process gas supply tube supplying the second process gas to the second region.

The above substrate processing apparatus may further include an upper plate, a middle plate, and a lower plate, which are vertically spaced apart from one another, wherein a space between the upper plate and the middle plate is the second region, and a space between the middle plate and the lower plate is the first region.

The middle plate may be applied with a radio frequency power, the lower plate may be grounded, and an insulation member may be provided between the middle plate and the lower plate.

The above substrate processing apparatus may further include an upper plate, a middle plate, and a lower plate, which are vertically spaced apart from one another, wherein a space between the upper plate and the middle plate is the first region, and a space between the middle plate and the lower plate is the second region.

The upper plate may be applied with a radio frequency power, the middle plate may be grounded, and an insulation member may be provided between the upper plate and the middle plate.

The above substrate processing apparatus may further include a plurality of injection nozzles passing through the lower plate from the middle plate.

The plasma generation part may include an ICP type first plasma generation part generating plasma inside the gas distribution part, and at least one second plasma generation part from among ICP-type, helicon type, and remote plasma type plasma generation parts that generate plasma outside the reaction chamber.

The above substrate processing apparatus may further include a magnetic field generation part provided inside the reaction chamber to generate a magnetic field in a reaction space between the substrate supporting member and the gas distribution part.

The magnetic field generation part may include first and second magnets, which are provided with the reaction space in-between and have polarities opposite to each other.

The above substrate processing apparatus may further include a filter part provided between the gas distribution part and the substrate supporting member to block a portion of the plasma of the process gas.

### BRIEF DESCRIPTION OF THE DRAWINGS

Exemplary embodiments can be understood in more detail from the following description taken in conjunction with the accompanying drawings, in which:

FIG. 1 is a schematic cross-sectional view illustrating a substrate processing apparatus in accordance with an embodiment;

FIG. 2 is an exploded perspective view of a gas distribution apparatus in accordance with an exemplary embodiment;

FIG. 3 is a partial exploded cross-sectional view of a gas distribution apparatus in accordance with an exemplary embodiment;

FIG. 4 is an exploded perspective view of a gas distribution apparatus in accordance with another exemplary embodiment;

FIG. 5 is a partial exploded cross-sectional view of a gas distribution apparatus in accordance with another exemplary embodiment;

FIG. 6 is a schematic cross-sectional view illustrating a substrate processing apparatus in accordance with another exemplary embodiment; and

FIGS. 7 and 8 are schematic cross-sectional views of a substrate processing apparatus in accordance with still another exemplary embodiment.

### DETAILED DESCRIPTION OF EMBODIMENTS

Hereinafter, exemplary embodiments of the present disclosure will be described in detail. The present disclosure may, however, be in different forms and should not be construed as limited to the embodiments set forth herein. Rather, these embodiments are provided so that this disclosure will be thorough and complete and will fully convey the scope of the present disclosure to those skilled in the art.

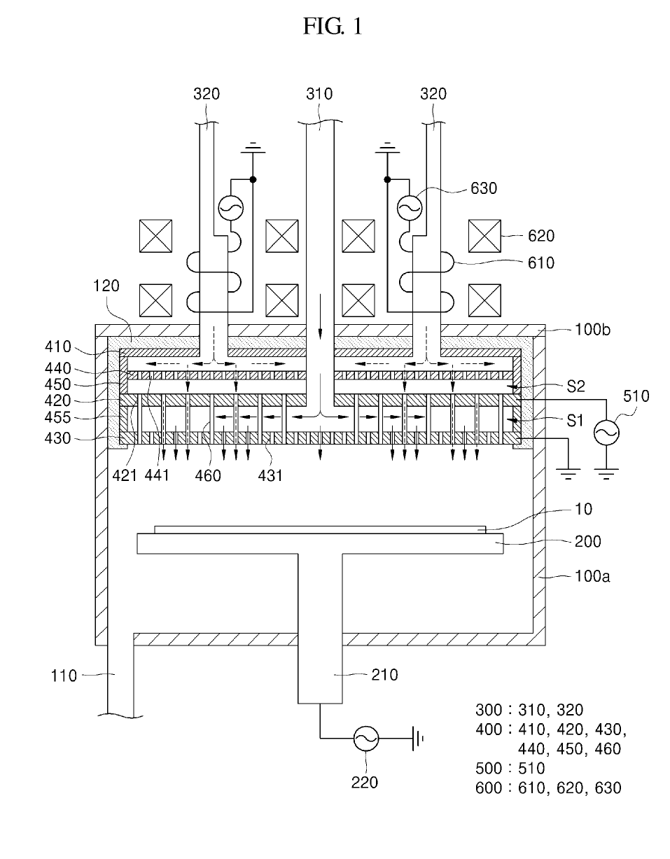

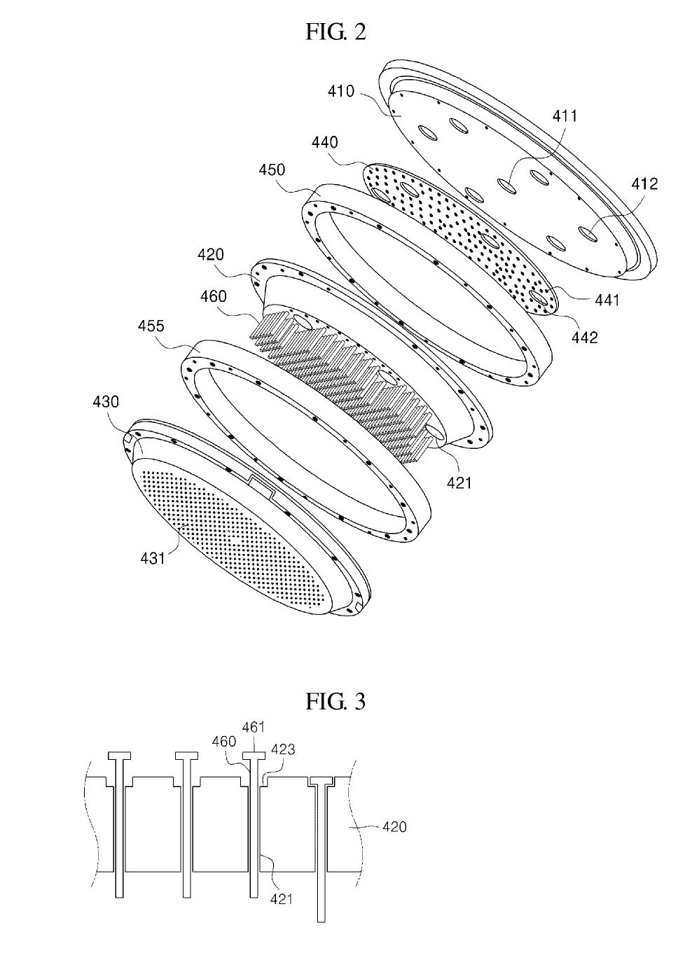

FIG. 1 is a schematic cross-sectional view of a substrate processing apparatus, and FIG. 2 is an exploded cross-sectional view of a gas distribution apparatus in accordance with an exemplary embodiment. Also, FIG. 3 is a partial exploded cross-sectional view of a gas distribution apparatus in accordance with an exemplary embodiment.

Referring to FIG. 1, a substrate processing apparatus in accordance with an exemplary embodiment includes: a reaction chamber 100 having a predetermined reaction space; a substrate supporting part 200 for supporting a substrate 10; a process gas supply part 300 for supplying a process gas; and a gas distribution part 400 provided in the reaction chamber to distribute at least two activated process gases. Also, the substrate processing apparatus may include a first plasma generation part 500 for generating plasma of a first process gas; and a second plasma generation part 600 which is provided outside the reaction chamber 100 to generate plasma of a second process gas. Herein, the second plasma generation part 600 may generate plasma with a density higher than that of the first plasma generation part 500.

The reaction chamber 100 defines a predetermined region and maintains the region to be sealed. The reaction chamber 100 may include a reaction part 100a including a planar part and a side wall part extending upwards from the planar part; and a lid 100b positioned on the reaction part 100a with an approximately circular shape and maintaining the reaction chamber to be sealed. Of course, the reaction part 100a and the lid 100b may be formed in various shapes in addition to the circular shape, for example, in a shape corresponding to the shape of the substrate 10. A discharge pipe 110 is connected to a side lower part of the reaction chamber 100, for example, under the substrate supporting part 200, and a discharge apparatus (not shown) is connected to the discharge pipe 110. Herein, a vacuum pump such as a turbo molecular pump may be used as the discharge apparatus, and accordingly, an inside of the reaction chamber 100 is configured to be under a reduced pressure environment, for example, to be suctioned by vacuum to a predetermined pressure of approximately 0.1 mTorr or less. The discharge pipe 110 may be provided at a lower portion as well as at a side surface in the reaction chamber. In addition, to reduce a discharge time, multiple discharge pipes 110 and corresponding discharge apparatuses may be further installed. Also, an insulation member 120 may be provided inside the reaction chamber to insulate the gas distribution part 400 from the reaction chamber 100. Meanwhile, an electromagnet (not shown) may be provided outside the side portion of the reaction chamber 100.

The substrate supporting member 200 is provided at a lower portion of the reaction chamber 100, and is provided at a position facing the gas distribution part 400. The substrate supporting member 200 may have, for example, an electrostatic chuck, etc. so that the substrate 10 introduced into the reaction chamber 100 may be seated. The substrate 10 may be maintained to be adsorbed to the electrostatic chuck by electrostatic force. Here, in addition to the electrostatic force, the substrate may also be maintained by vacuum adsorption or mechanical force. Also, although provided in an approximately circular shape, the substrate supporting member 200 may be provided in a shape corresponding to the shape of the substrate 10, and may be formed in a greater size than that of the substrate 10. Here, the substrate 10 may include an approximately circular silicon substrate for manufacturing a semiconductor device, and an approximately rectangular glass substrate for manufacturing a display device. A substrate lifter 210 moving up/down the substrate support member 200 is provided at a lower portion of the substrate support member 200. The substrate lifter 210 moves the substrate support member 200 to be adjacent to the gas distribution part 400 when the substrate 10 is seated on the substrate support member 200. Also, a heater (not shown) may be mounted inside the substrate support member 200. The heater generates heat up to a predetermined temperature to heat the substrate 10, so that a thin film deposition process etc. may be easily performed on the substrate 10. A halogen lamp is used as the heater, and may be provided around the substrate support member 200 about the substrate support member 200. Here, the generated energy heats the substrate support member 200 by convection energy to increase the temperature of the substrate 10. Meanwhile, a cooling tube (not shown) may be further provided inside the substrate support member 200. The cooling tube allows refrigerant to be circulated inside the substrate support member 200, so that a low temperature is transferred to the substrate to control the temperature of the substrate at a desired temperature. Of course, the heater and the cooling tube may be provided not in the substrate support member 200 but outside the reaction chamber 100. Accordingly, the substrate 10 may be heated by the heater provided inside the substrate support member 200 or outside the reaction chamber 100, and may be heated up to approximately 50° C. to approximately 800° C. by adjusting a number of the provided heaters. Meanwhile, a bias power source 220 is connected to the substrate support member 200, and energy of an ion incident to the substrate 10 by the bias power source 220 may be controlled.

A process gas supply part 300 include a plurality of process gas storages (not shown) respectively storing a plurality of process gases, and a plurality of process gas supply tubes 310 and 320 which supply the process gas from the process gas storages to the gas distribution part 400. For example, the first process gas supply tube 310 may pass through an upper central portion of the reaction chamber 100 to be connected to the gas distribution part 400, and the second process gas supply tube 320 may pass through an upper outer portion of the reaction chamber 100 to be connected to the gas distribution part 400. Here, at least one first process gas supply tube 310 may be provided, and a plurality of second process gas supply tubes 320 may be provided to surround the first gas supply tube 310. Also, although not shown, a valve, a mass flow controller, and etc., which control the supply of the process gas, may be provided in a predetermined region of the plurality of process gas supply tubes 310 and 320. Meanwhile, as a thin film deposition gas, for example, a silicon-containing gas and an oxygen-containing gas may be used. The silicon-containing gas may include SiH₄, etc., and the oxygen-containing gas may include O₂, H₂O, O₃, etc. Here, the silicon-containing gas and the oxygen-containing gas are supplied through the process gas supply tubes 310 and 320 different from each other. For example, the silicon-containing gas may be supplied through the first process gas supply tube 310, and the oxygen-containing gas may be supplied through the second process gas supply tube 320. Also, inert gases such as H₂, Ar, etc. may be supplied with the thin film deposition gas. The inert gases may be supplied through the first and second process gas supply tubes 310 and 320 together with the silicon-containing gas and the oxygen-containing gas. Meanwhile, since used as a plasma generation tube in which plasma of the process gas is generated, the second process gas supply tube 320 may be made of sapphire, quartz, ceramic, etc.

The gas distribution part 400 has a predetermined space therein, and may include a first region S1 receiving the first process gas and a second region S2 receiving the second process gas. This gas distribution part 400 may include an upper plate 410, a middle plate 420, and a lower plate 430, which are vertically spaced apart a predetermined distance from one another. Here, the second region S2 may be provided between the upper plate 410 and the middle plate 420, and the first region S1 may be provided between the middle plate 420 and the lower plate 430. Also, between the upper plate 410 and the middle plate 420, at least one diffusing plate 440 may be provided, and between the middle plate 420 and the lower plate 430, at least one insulation member 455 which maintains a gap and insulation between the middle plate 420 and the lower plate 430 may be provided. In addition, a plurality of injection nozzles 460 may be provided to pass through the lower plate 430 from the middle plate 420 through the first region S1. This gas distribution part 400 activates the first process gas received from the first region S1 into a plasma state, and receives the second process gas, which is activated into a plasma state outside the reaction chamber 100, through the second region S2. For this, the middle plate 420 and the lower plate 430 may respectively function as an upper electrode and a lower electrode for generating plasma in the first region therebetween. These structure and function of the gas distribution part 400 will be described below in detail with reference to FIGS. 2 and 3.

A first plasma generation part 500 is provided to excite the first process gas supplied into the reaction chamber 100 into a plasma state. For this, in an exemplary embodiment, the first plasma generation part 500 uses a CCP method. That is, the first plasma generation part 500 excites the process gas supplied to the first region S1 of the gas distribution part 400 into a plasma state. This first plasma generation part 500 may include an electrode provided in the gas distribution part 400, a first power supply part 510 applying a first radio frequency power to the electrode, and an earth power supply supplying an earth power to the electrode. The electrode may include the middle plate 420 and the lower plate 430, which are provided in the gas distribution part 400. That is, the first radio frequency power 510 is supplied to the middle plate 420, and the lower plate 430 is grounded, and thus plasma of the process gas is generated at the first region S1 between the middle plat 420 and the lower plate 430. For this, the middle plate 420 and the lower plate 430 may be made of conductive materials. The first power supply part 510 is connected to the middle plate 420 by penetrating through a side surface of the reaction chamber 100, and supplies the radio frequency power for generating plasma at the first region S1. This first power supply part 510 may include a radio frequency power supply and a matcher. The radio frequency power supply generates a radio frequency power of, for example, approximately 13.56 MHz. The matcher detects an impedance of the reaction chamber 100 and generates an imaginary impedance component with a phase opposite to an imaginary impedance component of the detected impedance, and thus maximum power may be supplied to the reaction chamber 100 such that the impedance is equal to a resistance which is a real impedance component. Thus, optimal plasma may be generated. The lower plate 430 may be connected to a side surface of the reaction chamber 100, and the reaction chamber 100 is connected to an earth terminal, so that the lower plate 430 also maintains an earth potential. Accordingly, when a radio power is applied to the middle plate 420, since the lower plate 430 maintains an earth state, a potential difference is generated between them, and thus the process gas is excited into a plasma state at the first region S1. Here, a gap between the middle plate 420 and the lower plate 430, that is, a vertical gap of the first region S1 is desirably maintained to be a minimum gap, where plasma may be excited, or more. For example, a gap of approximately 3 mm or more may be maintained. Thus, the process gas excited at the first region S1 is injected onto the substrate 10 through a through hole of the lower plate 430.

The second plasma generation part 600 generates plasma of the process gas outside the reaction chamber 100. For this, the second plasma generation part 600 may use at least one of an ICP type, a helicon type, and a remote plasma type, and a helicon method is described as an example in the current embodiment. This second plasma generation part 600 includes an antenna 610 provided to surround a plurality of second process gas supply tubes, a coil 520 provided around the second process gas supply tube 320 to generate a magnetic field, and a second radio frequency power supply 630 connected to the antenna 620. The second process gas supply tube 320 may be formed of sapphire, quartz, ceramic, etc., so that the plasma of the process gas may be generated therein, and is provided to have a predetermined barrel shape. The antenna 610 is provided to surround the second process gas supply tube 320 at an upper outside of the reaction chamber 100, and receives the second radio frequency power from the second radio frequency power supply 630 and excites the second process gas into plasma state in the second process gas supply tube 520. The antenna 610 is provided to have a tube shape, and allows cooling water to flow therein, thus preventing a temperature rise when a radio frequency power is applied. Also, the magnetic generating coil 620 is provided around the second process gas supply tube 320 so that radicals generated by plasma at the second gas supply tube 320 normally reach the substrate 10. In this second plasma generation part 600, when the second process gas is introduced from the process gas supply part 300 and the second radio frequency power is applied to the antenna 610 by the second frequency power supply 630 while the inside of the second process gas supply tube 320 is maintained at an appropriate pressure by discharged gas, plasma is generated in the second process gas supply tube 320. Also, current is allowed to flow in a direction opposite to each other in the magnetic field generation coils 620 so that a magnetic field is trapped in a space around the second process gas supply tube 320. For example, when current is allowed to flow in the coil 620 at an inner side of the second process gas supply tube 320 such that a magnetic field is generated in a direction toward the substrate 1, and current is allowed to flow in the coil 620 at an outer side of the second process gas supply tube 320 such that a magnetic field is generated in a direction opposite to the substrate 1, the magnetic field may be trapped in a space around the second process gas supply tube 320. Accordingly, although a distance between the second process gas supply tube 320 and the substrate 10 is small, the magnetic field is maintained at a low level around the substrate 10, and thus high density plasma may be generated under a relatively high vacuum and the substrate 10 may be treated with a small damage.

Referring to FIGS. 2 and 3, the gas distribution part will be described in more detail as follows.

The gas distribution part 400 may include an upper plate 410, a middle plate 420, and a lower plate 430, which are spaced apart by a predetermined distance from one another. Also, between the upper plate 410 and the middle plate 420, at least one diffusing plate 440 may be provided, and between the middle plate 420 and the lower plate 430, at least one insulation member 455 which maintains a gap between the middle plate 420 and the lower plate 430 and insulates them may be provided. In addition, a plurality of injection nozzles 460 may be provided to pass through the lower plate 430 from the middle plate 420 through the first region S1.

The upper plate 410 may be provided to have a plate shape corresponding to the shape of the substrate 10. That is, when the substrate has a circular shape, the upper plate 410 may be provided to have a circular plate shape, and when the substrate 10 has a rectangular shape, the upper plate 410 may be provided to have a rectangular plate shape. In the current embodiment, the case, where the gas distribution part 400 is provided to have a circular shape, and accordingly the upper plate 410, etc. have circular shapes, is described. In the upper plate 410, a plurality of insertion holes 411 and 412, into which the process gas supply tubes 310 and 320 are inserted, may be formed. That is, a first insertion hole 411 into which the first process gas supply tube 310 is penetratingly inserted is formed at a central portion of the upper plate 410, and a plurality of second insertion holes 412 through which a plurality of second process gas supply tubes 320 pass may be formed at an outer portion of the upper plate 410. Here, the diameters of the first and second insertion holes 411 and 412 are formed in accordance with the first and second process gas supply tubes 310 and 320 so that the latter may be inserted into the former. The diameters of the first and second insertion holes 411 and 412 may be the same or different. Meanwhile a flange is provided at an edge portion of the upper plate 410, and thus may be used for coupling of the insulation member 450 between the upper plate 410 and the middle plate 420.

The middle plate 420 may be provided to have a plate shape which is the same shape as that of the upper plate 410. That is, the middle plate 420 may be provided to have a plate shape corresponding to the shape of the substrate 10. Also, a plurality of through holes are formed in the middle plate 420. The plurality of injection nozzles may be inserted into the plurality of through holes 421. Also, an insertion hole 422, through which the first process gas supply tube 310 is penetratingly inserted, is formed at a central portion of the middle plate 420. Here, a region between the upper plate 410 and the middle plate 420 becomes the second region S2, and the process gas activated outside the reaction chamber 100 is supplied to the second region S2. That is, the second process gas supply tube 320 passes through the upper plate 410 and an outlet thereof is located at the second region S2. Since the process gas activated by plasma outside the reaction chamber 100 is supplied by the second process gas supply tube 320, the activated process gas is supplied to the region S2. Also, a stepped portion 423 having a predetermined thickness may be formed at an upper portion thereof as illustrated in FIG. 3. That is, an upper portion of the through hole 421 is recessed to have a diameter greater than the diameter of the through hole 421, and the recessed portion becomes the stepped portion 423. The stepped portion 423 allows an upper portion of the injection nozzle 460 to be placed thereon, so that the injection nozzle 460 may be supported by the middle plate 420.

Meanwhile, at least one diffusing plate 440 may be provided between the upper plate 410 and the middle plate 420. The diffusing plate 440 is provided to uniformly diffuse the activated process gas supplied to the second region S2 over the second region S2. That is, since the diffusing plate 440 is vertically provided in the second region S2, a process gas is supplied to an upper side of the diffusing plate 440, and is diffused by the diffusing plate 440, so that the process gas may be uniformly distributed over the second region S2. Here, a plurality of through holes are formed in the diffusing plate 440. That is, a plurality of through holes are formed in the diffusing plate 440 to uniformly distribute the process gas supplied to the second region S2 and move the distributed gas toward the middle plate 420. Here, the plurality of through holes formed in the diffusing plate 440 may be formed to have the same size and interval, or have different sizes and intervals. For example, since a greater amount of the process gas is supplied to a region located just under the second process gas supply tube 320, the through holes 441 located just under the second process gas supply tube 320 may have smaller sizes and as becoming farther from the second process gas supply tube 320, the through holes 441 may have larger sizes. Also, the through holes 441 located just under the second process gas supply tube 320 may have larger intervals therebetween, and as becoming farther from the second process gas supply tube 320, the through holes 441 may have smaller intervals therebetween. That is, when the sizes of the through holes 441 are formed to be the same, as becoming farther from the second process gas supply tube 320, the intervals between the through holes 441 may be formed to be smaller. Also, when the intervals between the through holes 441 are formed to be the same, as becoming farther from the second process gas supply tube 320, the size of the through holes 441 may be formed to be larger. Meanwhile, an insertion hole 442, through which the first process gas supply tube 310 is penetratingly inserted, may be formed at a central portion of the diffusing plate 440. That is, the first process gas supply tube 310 may extend up to a lower side of the middle plate 420 after penetrating the insertion holes 442 of the diffusing plate 440 and the insertion holes 422 of the middle plate 420

Meanwhile, the insulation member 450 is provided between the upper plate 410 and the middle plate 420 to maintain the distance between the upper plate 410 and the middle plate 420 and to be insulated from each other. Accordingly, the width of the first region S1 may be determined in accordance with the thickness of the insulation member 450. The insulation member 450 may be provided to have, for example, a ring shape so as to be provided between the upper plate 410 and an edge region of the middle plate 420. Also, the diffusing plate 440 may be provided at an inner side of the insulation member 450. Meanwhile, a second insulation member 455 may be further provided between the middle plate 420 and the lower plate 430 to insulate the middle plate 420 and the lower plate 430.

The lower plate 430 is spaced from the middle plate 420 and is provided under the middle plate 420. The lower plate 430 is provided to have the same size as the upper plate 410 and the middle plate 420, and is provided to have an approximately circular plate shape. A region between the middle plate 420 and the lower plate 430 becomes the first region S1. The process gas is supplied to the first region S1 from the first process gas supply part 310. Also, a plurality of through holes 431 are formed in the lower plate 430. The plurality of injection nozzles 460 may be inserted into a portion of the plurality of through holes 431. Accordingly, the number of formed through holes 431 of the lower plate 430 is more than that of the through holes 421 of the middle plate 420, for example, may be twice the number of through holes 421 of the middle plate 420. That is, one portion of the through holes 431 of the lower plate 430 may inject activated gas in the region S1 toward the lower side, and the injection nozzles 460 are inserted into the other portion of the through holes 431. Here, the through holes 421 into which the injection nozzle 460 is inserted and the through holes 421 into which the injection nozzle 460 is not inserted may be disposed adjacent to each other. That is, to uniformly inject the second process gas injected through the injection nozzle 460 and the first process gas injected through the through holes 431, the through holes 421 may be disposed uniformly and adjacent to each other. Meanwhile, the middle plate 420 and the lower plate 430 function as an electrode for activating the first process gas supplied to the first region S1. For example, radio frequency power is applied to the middle plate 420, and the lower plate 430 is grounded, and thus the process gas supplied to the first region S1 may be excited into a plasma state. Also, insulation members 455 are provided between the middle plate 420 and the lower plate 430 to maintain the distance between the middle plate 420 and the lower plate 430 and to insulate the middle plate 420 and the lower plate 430 from each other. Accordingly, the width of the first region S1 may be determined in accordance with the thicknesses of the insulation members 460. The insulation members 460 may be provided to have, for example, a ring shape so as to be provided between the middle plate 420 and an edge region of the lower plate 430.

The injection nozzle 460 may be provided to have a tube shape with a predetermined length and a diameter. This injection nozzle 460 may be inserted into the lower plate 430 from the middle plate 420 through the first region S1. That is, the injection nozzle 460 may be inserted into the through holes 421 of the middle plate 420 and the through holes 431 of the lower plate 430, which is spaced apart from each other with the first region S1 therebetween. Accordingly, the process gas, which is activated from the outside and is supplied to the region S2, may be injected onto the substrate 10 through the injection nozzle 460. Meanwhile, since the middle plate 420 and the lower plate 430 are formed of conductive materials and may respectively function as an upper electrode and a lower electrode, the injection nozzle 460 may be formed of an insulating material to insulate the middle plate 420 and the lower plate 430. Meanwhile, the injection nozzle 460 may have a head 461 having a larger width than other regions thereof at an upper portion thereof as illustrated in FIG. 3. The head is supported by being stopped by the stepped portion 423 of the middle plate 420. That is, the body of the injection nozzle 460 is penetratingly inserted into the through holes 421 of the middle plate 420, and the head of the injection nozzle 460 is stopped by the stepped portion 423 of the middle plate 420, and thus the injection nozzle 460 may be supported by the middle plate 420.

As described above, the gas distribution part 400 of the substrate processing apparatus in accordance with an exemplary embodiment has the first region S1 and the second region S2 which are vertically spaced apart from each other. Any one of the first and second regions S1 and S2 accommodates the process gas which is excited into a plasma state outside the reaction chamber 100, and the other one excites the process gas supplied to the gas distribution part 400. That is, at least a portion of the gas distribution part 400 in accordance with an exemplary embodiment is used as electrodes for exciting the process gas. For example, the gas distribution part 400 includes the upper plate 410, the middle plate 410, and the lower plate 430, which are vertically spaced apart a predetermined distance from one another. The process gas excited into a plasma state outside the reaction chamber 100 is supplied to the second region S2 between the upper plate 410 and the middle plate 420, and the process gas supplied to the first region S1 between the middle and lower plates 420 and 430 is excited to a plasma state by the middle and lower plates 420 and 430 which respectively function as an upper and lower electrodes. Also, the injection nozzle 460 is provided to pass through the middle plate 420, the first region S1, and the lower plate 430 to inject the excited process gas of the second region S2 onto the substrate 10. Accordingly, since the plasma of the process gas is not generated on the substrate 10 in the reaction chamber 100, damage to the substrate 10 due to the plasma may be prevented.

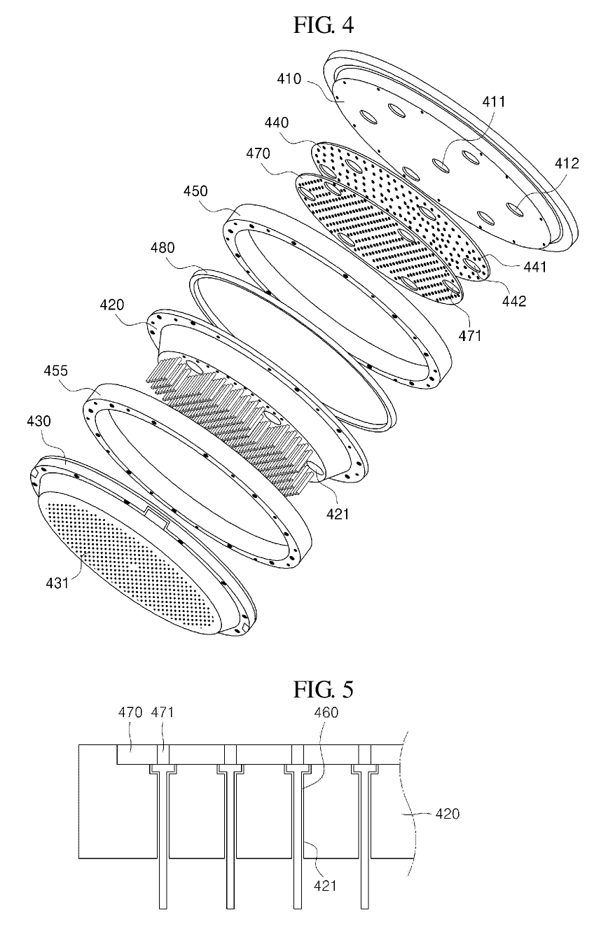

Also, the gas distribution part 400 of an exemplary embodiment may further include a cover plate 470 between the diffusing plate 440 and the middle plate 420 as illustrated in FIGS. 4 and 5. Also, a gap adjusting member 480 may be further included between the middle plate 420 or the lower plate 430 and the insulation member 450.

The cover plate 470 may be provided between the diffusing plate 440 and the middle plate 420 to contact the upper surface of the middle plate 420. Here, the cover plate 470 is provided to cover the injection nozzle 460 of which the head part 461 is supported by the stepped portion 423 of the middle plate 420 and which is inserted into the middle plate 420. As the cover plate 470 is provided, the accumulation of particles of the process gas between the middle plate 420 and the injection nozzle 460 may be prevented. Also, a step may be formed at the portion to which the cover plate 470 of the middle plate 420. That is, a step may be formed having a height of a thickness of the cover plate 470 between a central region of an upper surface of the middle plate 420 which the cover plate 470 contacts and an edge if the middle plate 420 which one surface of the cover plate 470 does not contact. The edge of the middle plate 420 is higher than the upper surface of the middle plate 420 by a thickness of the cover plate 470. Accordingly, after the cover plate 470 is mounted on the middle plate 420, the edge of the middle plate 420 and the cover plate 470 may become coplanar. Also, a plurality of through holes 471 are formed in the cover plate 470, and a through hole 472, into which the first process gas supply tube 310 is inserted, are formed at a central portion of the cover plate 470. The plurality of through holes 471 may be formed at the same position and to have the same size as the plurality of through holes 421 formed in the middle plate 420. That is, the plurality of through holes 471 overlaps the plurality of through holes 421 of the middle plate 420.

At least one gap adjusting member 480 may be provided to adjust a gap between the middle plate 420 and the lower plate 430. That is, the gap between the middle plate 420 and the lower plate 430, that is, the gap of the first region S1 is fixed by the thickness of the insulation member 455. By inserting at least one gap adjusting member 480 into a lower side or an upper side of the insulation member 455, the gap of the first region S1 may be adjusted in accordance with the thickness of the gap adjusting member 480. This gap adjusting member 480 may be provided to have the same shape as the insulation member 455, for example, a ring shape, and may be provided to have the same diameter as the insulation member 455.

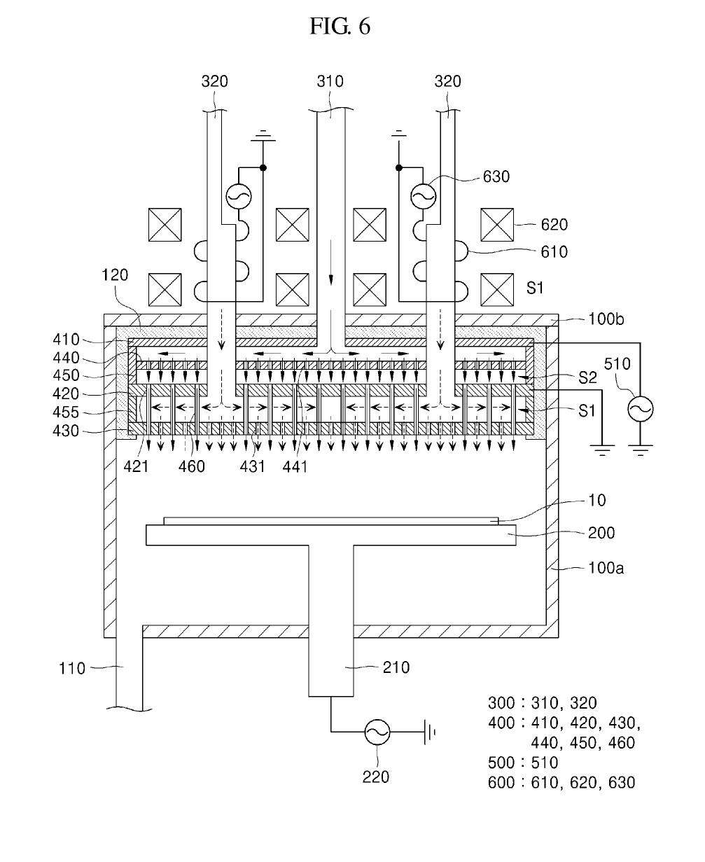

Meanwhile, the gas distribution part in accordance with an exemplary embodiment generates the plasma of the first process gas at the first region S1 in the lower portion thereof, and accommodates the second process gas which is excited into a plasma state from the outside and is supplied to the second region S2 in an upper portion thereof. However, the gas distribution part of an exemplary embodiment, as illustrated in FIG. 6, may accommodates the second process gas, which is excited into a plasma state and supplied from the outside, in the first region S1, and may generate the plasma of the first process gas in the second region S2 between the upper plate 410 and the middle plate 420. For this, power is supplied to the upper plate 410 from the first power supply part 510, and the middle plate 420 is grounded. Here, the injection nozzle 460 may pass through the first region S1 from the second region S2 and extend to an inner space of the reaction chamber 100, and inject the second process gas which is in a plasma state generated in the second region S2.

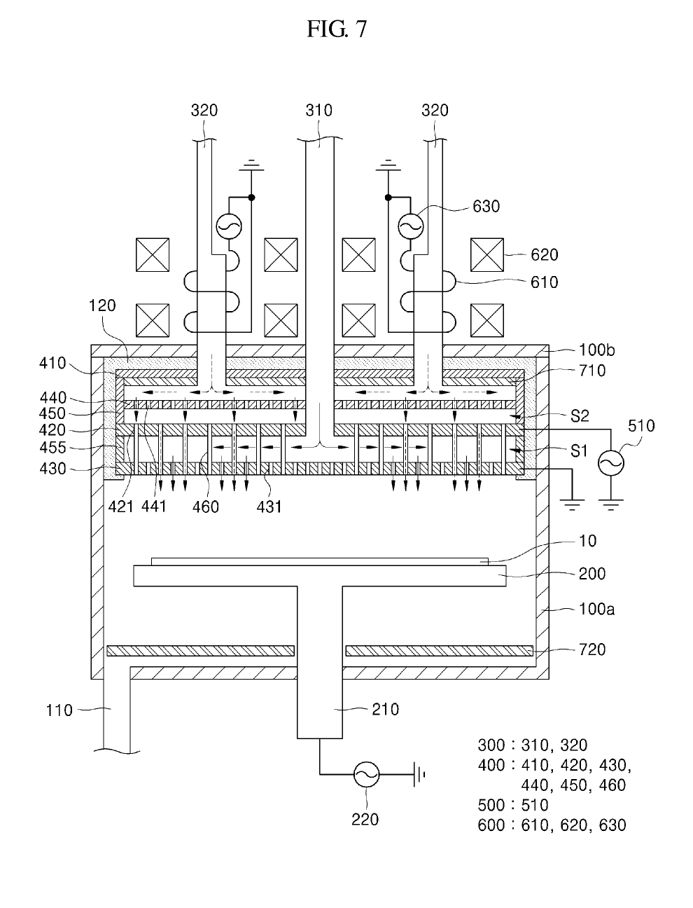

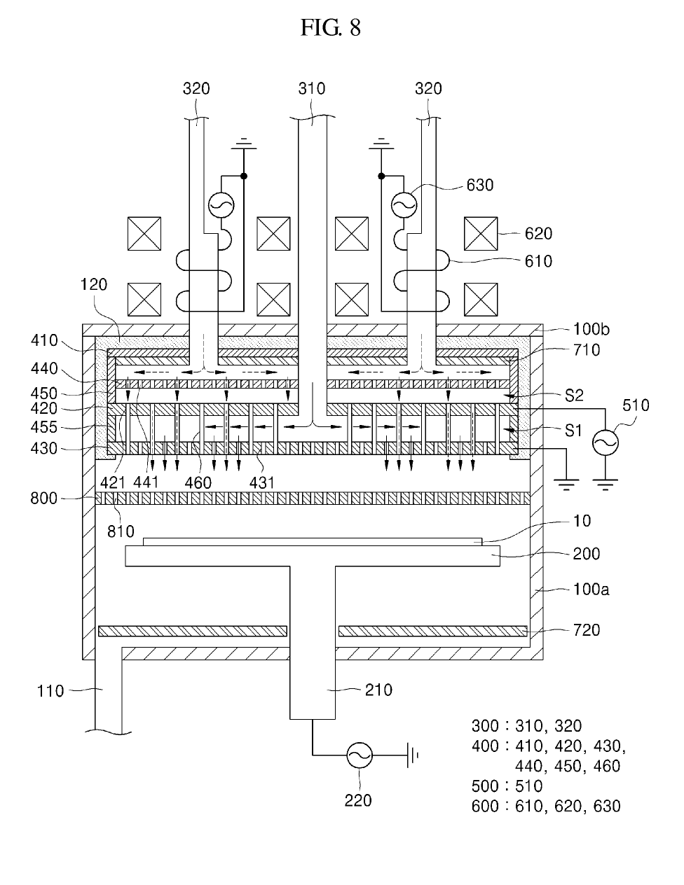

Also, the substrate processing apparatus including the above-described gas distribution part may be variously modified, and these various embodiments of the substrate processing apparatus will be described below with reference to FIGS. 7 and 8.

FIG. 7 is a schematic cross-sectional view of a substrate processing apparatus in accordance with an exemplary embodiment, in which a magnetic field generation part 700, which is provided inside the reaction chamber 100 and generates a magnetic field for activating plasma, may be further included. That is, a substrate processing apparatus in accordance with another exemplary embodiment may include a reaction chamber 100 defining a predetermined reaction space; a substrate support part 200 provided at an inner lower portion of the reaction chamber 100 and supporting a substrate 10; a process gas supply part 300 supporting process gas; a gas distribution part 400 provided inside the reaction chamber 100 and distributes at least two activated process gases; a first plasma generation part 500 for generating plasma of a first process gas inside the gas distribution part 400; a second plasma generation part 600 provided outside the reaction chamber 100 to generate plasma of a second process gas; and a magnetic field generation part 700 provided inside the reaction chamber 100 to generate a magnetic field for activating the plasma.

The magnetic field generation part 700 is provided inside the reaction chamber 100 to generate a magnetic field inside the reaction chamber 100. This magnetic field generation part 700 may include, for example, a first magnet 710 provided at an upper portion of the gas distribution part 400, and a second magnet 720 provided at a lower portion of the substrate supporting member 200. That is, the first magnet 710 may be provided between the gas distribution part 400 and a lid of the reaction chamber 100, and the second magnet 720 may be provided at an inner bottom surface of the reaction chamber 100 under the substrate supporting member 200. However, the first and second magnets 710 and 720 may be provided at a region in which the plasma treatment is performed, that is, at any portions of a lower portion of the gas distribution part 400 and an outer portion of an upper region of the substrate supporting member 200. For example, the first magnet 710 may be provided at an inner upper portion of the gas distribution part 400, that is, at the second region S2, and the second magnet 720 may be provided between the substrate supporting member 200 and the bottom surface of the reaction chamber 100. Also, the first and second magnets 710 and 720 may be provided to have polarities different from each other. That is the first and second magnets 710 and 720 may be provided as a single magnet having N and S poles respectively, or as a single magnet having S and N poles respectively. These first and second magnets 710 and 720 may be provided as a permanent magnet, an electromagnet, etc., and a case may be provided such that the magnets are provided therein and the case surrounds the magnets from the outside. That is, the first and second magnets 710 and 720 may be manufactured such that the permanent magnet, the electromagnet, etc, may be provided in the case having a predetermined inner space. Here, the case may be formed of, for example, an aluminum material. Also, the first and second magnets 710 and 720 may be provided as a single magnet, and may be provided to have a shape and a size of the substrate 10. Meanwhile, the first magnet 710 may have an opening into which the first and second process gas supply tubes 310 and 320 are inserted, and the second magnet 720 may have an opening in which a substrate lifter 210 moves up and down. Since the first and second magnets 710 and 720 having polarities different from each other are respectively provided at upper and lower portions of the reaction chamber 100, a magnetic field is generated vertically in the reaction chamber 100. The plasma may be activated by this magnet field generated vertically, and accordingly, the density of the plasma may be improved. That is, at a lower portion as well as an upper portion of the reaction chamber 100, plasma may be generated to have an approximately same density. Accordingly, the density of the plasma may be maintained high, so that quality of thin film deposited on the substrate 10 may be improved and an etching rate of the thin film may be improved.

FIG. 8 is a cross-sectional view of a substrate processing apparatus in accordance with another exemplary embodiment.

Referring to FIG. 8, a substrate processing apparatus in accordance with another exemplary embodiment may include a reaction chamber 100 defining a predetermined reaction space; a substrate support part 200 provided at an inner lower portion of the reaction chamber 100 to support a substrate 10; a process gas supply part 300 for supplying a process gas; a gas distribution part 400 provided inside the reaction chamber 100 to distribute at least two activated process gases; a first plasma generation part 500 for generating plasma of a first process gas inside the gas distribution part 400; a second plasma generation part 600 provided outside the reaction chamber 100 to generate plasma of a second process gas; and a filter part 800 provided between the substrate supporting part 200 and the gas distribution part 400. Also, a magnetic field generation part 700 provided inside the reaction chamber 100 to generate a magnetic field for activating the plasma may be further included.

The filter part 800 is provided between the substrate supporting part 200 and the gas distribution part 400, and has a side surface connected to a side wall of the reaction chamber 100. Accordingly, the filter part 800 may maintain an earth potential. This filter part 800 filters ions, electrons and light of the plasma injected from the gas distribution part 400. That is, when the excited process gas injected from the gas distribution part 400 pass through the filter part 800, the ions, electrons and light are blocked and only a reaction seed may be reacted with the substrate 10. This filter part 800 allows the plasma to collide with the filter part 800 at least once and to be applied then to the substrate 10. Through this, when the plasma collides with the filter part 800 with an earth potential, ions and electrons having large energy may be absorbed. Also, the light of the plasma collides with the filter part 800 and may not transmit. This filter part 800 may be provided to have various shapes, for example, may be formed as a single plate having a plurality of through holes 810 formed therein; may be formed such that plates, in which the through holes 810 are formed, are provided in multi-layers such that the through holes 810 of each of the plates are misaligned with each other; or may also be formed to have a plate shape such that a plurality of through holes 810 have a predetermined bent path.

A gas distribution apparatus of a substrate proceeding apparatus in accordance with exemplary embodiments includes first and second regions vertically separated therein. Any one of the first and second regions accommodates the process gas supplied after being excited into a plasma state from the outside and the other one excites the process gas supplied to the gas distribution part into a plasma state. That is, at least a portion of the gas distribution part 400 in accordance with an exemplary embodiment is used as electrodes for exciting the process gas. Accordingly, since the plasma of the process gas is not generated on a substrate, the damage to the substrate due to plasma may be prevented.

Also, since the process gases excited through methods different from each other, process uniformity on the substrate may be improved.

Although the gas distribution apparatus and a substrate processing apparatus including the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A gas distribution apparatus comprising first and second regions vertically separated therein, wherein
in the first region, a first process gas supplied to the first region from the outside is injected after being excited into a plasma state, and
in the second region, a second process gas supplied after being excited into a plasma state from the outside is injected after being accommodated.

2. The apparatus of claim 1, comprising an upper plate, a middle plate, and a lower plate, which are vertically spaced apart from one another, wherein a space between the upper plate and the middle plate is the second region, and a space between the middle plate and the lower plate is the first region.

3. The apparatus of claim 2, wherein the middle plate is applied with a radio frequency power, the lower plate is grounded, and a insulation member is provided between the middle plate and the lower plate.

4. The apparatus of claim 1, comprising an upper plate, a middle plate, and a lower plate, which are vertically spaced apart from one another, wherein a space between the upper plate and the middle plate is the first region, and a space between the middle plate and the lower plate is the second region.

5. The apparatus of claim 4, wherein the upper plate is applied with a radio frequency power, the middle plate is grounded, and an insulation member is provided between the upper plate and the middle plate.

6. The apparatus of claim 2, further comprising a plurality of injection nozzles penetrating the lower plate from the middle plate.

7. The apparatus of claim 6, wherein
the middle plate is formed with a plurality of first through holes through which the plurality of nozzles pass; and
the lower plate is formed with a plurality of second through holes through which the plurality of nozzles pass, and
a plurality of third through holes injecting the process gas into a region between the middle plate and the lower plate.

8. The apparatus of claim 6, wherein the second and third through holes are formed with the same size and number.

9. The apparatus of claim 6, wherein a stepped portion having a diameter larger than that of the first through hole is provided at an upper portion of the first through hole of the middle plate, and an upper portion of the injection nozzle is supported by the stepped portion.

10. The apparatus of claim 6, further comprising a cover plate having one surface contacting an upper surface of the middle plate and a plurality of through holes formed therein.

11. The apparatus of claim 2, further comprising at least one of a diffusing plate provided between the upper plate and the middle plate and having a plurality of through holes formed therein, and a gap adjusting member provided on at least one portion of upper and lower sides of the insulation member and having a same shape as the insulation member.

12. A substrate processing apparatus comprising:
a reaction chamber having a predetermined reaction space;
a substrate support part provided within the reaction chamber to support a substrate;
a gas distribution part 400 provided to face the substrate supporting member and comprising first and second regions vertically separated therein, wherein in the first region, a first process gas supplied to the first region from the outside is injected after being excited into a plasma state, and in the second region, a second process gas supplied after being excited into a plasma state from the outside is injected after being accommodated; and
a plasma generation part for generating plasma of a process gas outside the reaction chamber and inside the gas distribution part.

13. The apparatus of claim 12, further comprising a process gas supply part comprising a first process gas supply tube supplying the first process gas to the first region, and a second process gas supply tube supplying the second process gas to the second region.

14. The apparatus of claim 13, comprising an upper plate, a middle plate, and a lower plate, which are vertically spaced apart from one another, wherein a space between the upper plate and the middle plate is the second region, and a space between the middle plate and the lower plate is the first region.

15. The apparatus of claim 14, wherein the middle plate is applied with a radio frequency power, the lower plate is grounded, and an insulation member is provided between the middle plate and the lower plate.

16. The apparatus of claim 13, comprising an upper plate, a middle plate, and a lower plate, which are vertically spaced apart from one another, wherein a space between the upper plate and the middle plate is the first region, and a space between the middle plate and the lower plate is the second region.

17. The apparatus of claim 16, wherein the upper plate is applied with a radio frequency power, the middle plate is grounded, and an insulation member is provided between the upper plate and the middle plate.

18. The apparatus of claim 14, further comprising a plurality of injection nozzles passing through the lower plate from the middle plate.

19. The apparatus of claim 12, wherein the plasma generation part comprises
an ICP type first plasma generation part generating plasma inside the gas distribution part; and
at least one second plasma generation part from among ICP type, helicon type, and remote plasma type plasma generation parts that generates plasma outside the reaction chamber.

20. The apparatus of claim 13, further including at least one of a magnetic field generation part provided within the reaction chamber to generate a magnetic field in a reaction space between the substrate supporting member and the gas distribution part; and a filter part provided between the gas distribution part and the substrate supporting member to block a portion of the plasma of the process gas.
